(19) United States
(12) Patent Application Publication
(10) Pub. No.: US 2010/0021280 A1
(43) Pub. Date: Jan. 28, 2010

(54) STORAGE AND TRANSFER OF ORGANIC NANOFIBERS

(75) Inventors: Horst-Günter Rubahn, Odense No (DK); Kasper Thilsing-Hansen, Orbaek (DK)

Correspondence Address: FOLEY AND LARDNER LLP;SUITE 500, 3000 K STREET NW, WASHINGTON, DC, 20007, US

(73) Assignee: Syddansk Universitet

(21) Appl. No.: 12/526,639

(22) PCT Filed: Feb. 12, 2008
(86) PCT No.: PCT/DK2008/050035

§ 371 Date: Oct. 6, 2009

(30) Foreign Application Priority Data
Feb. 12, 2007 (DK) PA 2007 00226

(51) Int. Cl. H01L 51/56; B32B 3/00

(52) U.S. Cl. 414/800; 428/156

(57) ABSTRACT

The present invention relates to a method of transferring nanofibres from a template substrate (30) to a flexible storage medium (32). The method comprising: a) providing the template substrate (30) supporting nanofibres (31) and the flexible storage medium (32); b) positioning the flexible storage medium (32) so that a first storage area of the flexible storage medium is facing a first support area of the template substrate (30); and c) pressing (36) the first storage area of the flexible storage medium (32) in contact with the first support area of the template substrate (30) and remove the first storage area of the flexible storage medium from contact with the first support area of the template substrate, thereby transferring the nanofibres (31) from the template substrate (30) to the flexible storage medium (32) and thereby providing a loaded flexible storage medium. The present invention is advantageous for providing a method of storing and handling of nanofibres for commercial implementation into working devices, by providing a solution to problems concerning compact storage of nanofibres for further use.

### FIELD OF THE INVENTION

The present invention relates to storage of nanofibres and in particular to transferring of nanofibres from a template substrate to a storage medium.

### BACKGROUND OF THE INVENTION

The ongoing rapid miniaturisation of optoelectronics has led to an increased interest in generation, characterisation and interconnection of optoelectronic elements with characteristic dimensions in the sub-micrometer or nanometer length scale regime. The requirements of the optically active element(s) in a sub-micro- or nanoscale optoelectronic component include such features as an easy optical tunability, a strong luminescence efficiency, flexibility in the molecular basis elements and that light should be generated or propagate in a predefined way. Organic optically active elements may fulfil such requirements.

A difficulty is that normally it is impossible, inconvenient or economically unfeasible to form the organic sub-micro- or nanoscale optically active elements and components directly on a desired substrate.

A solution to this is to form the optically active element on a different substrate—a formation substrate or template—and subsequently transfer the element to the desired substrate.

The published patent application WO 2006/048015 discloses a lift-off procedure for releasing an ensemble of organic nanofibres from a template substrate so that it subsequently may be transferred to a target substrate or a liquid solution.

In the product line of an electronic component incorporating nanoscale or sub-microscale elements as the active elements, different production steps may be performed at different locations, at different production times, in different production runs, etc. In such situations a problem may arise in connection with storage of the nanoscale or sub-microscale elements or components produced at a first substrate, between production of the active element and incorporation of the active element into the electronic component.

The inventors of the present invention have appreciated that an improved way of handling sub-micro- or nanoscale elements is of benefit, and has in consequence devised the present invention.

### SUMMARY OF THE INVENTION

The present invention seeks to provide an improved means of handling an ensemble of organic nanofibres, and it may be seen as an object of the invention that an ensemble of organic nanofibres may be transferred to a storage medium in a way so that at least one of the following properties of the organic nanofibres: morphology, optical, electronic and/or mechanical are maintained in a substantially unaltered form. It is a further object of the present invention to provide an alternative to the prior art. In particular, it may be seen as an object of the present invention to provide a method of transferring nanofibres from a template substrate to a flexible storage medium that solves the above mentioned or other problems of the prior art.

Preferably, the invention alleviates or mitigates one or more of the above or other disadvantages singly or in any combination. Accordingly there is provided, in a first aspect, a method of transferring nanofibres from a template substrate to a flexible storage medium, the method comprising:

a) providing the template substrate supporting nanofibres and the flexible storage medium;
b) positioning the flexible storage medium so that a first storage area of the flexible storage medium is facing a first support area of the template substrate;
c) pressing the first storage area of the flexible storage medium in contact with the first support area of the template substrate and remove the first storage area of the flexible storage medium from contact with the first support area of the template substrate, thereby transferring the nanofibres from the template substrate to the flexible storage medium and thereby providing a loaded flexible storage medium.

The template substrate may be any type of substrate suitable for supporting an ensemble of nanofibres. The template substrate may be a dielectric substrate, and the substrate may have a polar surface, i.e. a surface which maintains an electrical field. Such substrates may be unstable in ambient conditions and consequently at least one of the steps required in order to provide the template substrate supporting nanofibres, may include preparing the template substrate and growing nanofibres in a vacuum condition, such as in a pressure below 10⁻⁵ torr, such as below 10⁻⁷ torr, or even lower. The template substrate may be a mica substrate, such as a mica substrate of the muscovite type. However, the template substrate may be any type of polar substrate such as surfaces maintaining a non-zero electrical charge and a non-zero surface dipole moment, e.g. such as surfaces of the {111}-terminated rocksalt crystals, the {0001}-terminated wurtzite crystals, the {110}-terminated fluorite crystals, etc.

The term nanofibres should be construed broadly to include elongated objects or aggregates with at least one characteristic dimension in the nanoscale. Moreover, the prefix nano should be construed broadly and at least to include sub-micrometer sized objects as is common in the field of nanotechnology. Reference is made to nanofibres, this reference is not intended to be limiting and should be construed to include at least rod-like shapes, needle-like shapes, such as any type of elongated or substantially elongated and bent objects.

The nanofibres may be organic nanofibres, e.g. provided as the resulting structure of a growth process, where the nanofibres are build up of individual organic molecules so at to obtain elongated or bent aggregates of molecules. The individual organic molecules may be molecules with a π-electronic configuration. The organic molecules may be of the type of para-phenylene oligomers or functionalised para-phenylene oligomers.

The nanofibres may have a mean lengths in the range of 10 to 100 microns or even longer. The cross-sectional width may be a few hundred nanometers and a cross-sectional height of approximately 100 nanometer. The shape of the cross-sectional area may be generally rectangular or quadratic. However, any cross-sectional shape may be envisioned.

The flexible storage medium may be in the form of a band, such as a plastic band, including a PET band. A plastic band is cheap, ready available and reliable.

Embodiments of the present invention is particularly but not exclusively advantageous for providing a method of storing and handling of nanofibres for commercial implementation into working devices, by providing a solution to problems concerning compact storage of nanofibres for further use.

The method may further comprise the subsequent steps of:

b2) repositioning the flexible storage medium and optionally the template substrate so that at least a second storage area of the flexible storage medium is facing at least a second support area of the template substrate,
c2) pressing the second storage area of the flexible storage medium in contact with the at least second support area of the template substrate and remove the at least second storage area of the flexible storage medium from contact with the at least second support area of the template substrate
or alternatively, the steps of:
a3) providing nanofibres onto the same or other template substrate;
b3) repositioning the flexible storage medium so that at least a second storage area of the flexible storage medium is facing a first support area of the template substrate.
c3) pressing the second storage area of the flexible storage medium in contact with the first support area of the template substrate and remove the at least second storage area of the flexible storage medium from contact with the first support area of the template substrate.

Sequentially loading of a number of areas of the storage medium may thereby be performed, in order to provide a flexible storage medium storing a large number of areas containing nanofibres.

Having loaded the flexible storage medium, the loaded flexible storage medium may be stored, in principle for an indefinite period. For ensuring cleanliness, or for other reasons, the storage of the flexible storage medium may be done in a controlled atmosphere, such as in a nitrogen atmosphere, in a carbon dioxide atmosphere, in a noble gas atmosphere or generally in an inactive atmosphere.

The stored nanofibres may be transferred to a target substrate by the following steps:

d) providing a target substrate; e) positioning the loaded flexible storage medium so that a first storage area of the loaded flexible storage medium is facing a first support area of the target substrate;
f) pressing the first storage area of the loaded flexible storage medium in contact with the first support area of the target substrate and remove the first storage area of the flexible storage medium from contact with the first support area of the target substrate, thereby transferring the nanofibres from the loaded flexible storage medium to the target substrate.
The transfer process may include the steps:
e2) repositioning the loaded flexible storage medium and optionally the target substrate so that at least a second storage area of the loaded flexible storage medium is facing at least a second support area of the target substrate.
f2) pressing the second storage area of the loaded flexible storage medium in contact with the at least second support area of the target substrate and remove the at least second storage area of the loaded flexible storage medium from contact with the at least second support area of the target substrate.

At least some of the process steps of transferring the nanofibres from the flexible storage medium to the target substrate may in some embodiment be similar as to the process steps of transferring the nanofibres from the template substrate to the flexible storage medium, except for the start substrate and the end substrate.

The target substrate may be any desired substrate, such as a semiconductor substrate, e.g. a silicon substrate, a GaAs-substrate, an InP-substrate, etc. However, the target substrate may also be an insulator substrate, such as an alumina substrate, a silica substrate, a glass substrate, etc. The target substrate may also be a metal substrate, an oxide substrate, such as an ITO-substrate, etc. Further processing may be performed on the target substrate, e.g. in order to fabricate a device.

Embodiments of the present invention is particularly but not exclusively advantageous for being able to provide a solution to the problem of local transfer of nanofibres onto an in principle arbitrary, or at least a variety, of target substrates.

In connection with pressing a storage area of the flexible storage medium in contact with a support area of the template substrate or target substrate, the contact may be such contact where short-range atomic or molecular attraction arises between the template substrate and the flexible storage medium or between the flexible storage medium and the target substrate.

The pressing may be done by means of a stamp, pressing from the backside of the flexible storage medium. In an embodiment, the stamping is done by means of compressed air. By applying compressed air, it may be ensured that the entire face of the flexible storage medium is pressed in contact with the desired area of the template substrate or target substrate.

Additional process steps may be performed in between the multiple transfer steps of embodiments of the present invention, such as lithographic steps, deposition steps, etc. In an embodiment, the growth of the nanofibres on the template substrate may be patterned, e.g. so that some regions contain nanofibres and others are void. The patterning may be transferred to the flexible storage medium and the target substrate to provide a given functionality in a resulting device.

The transfer process may prior to the steps a) or a3) above include releasing the nanofibres from the template substrate by first providing a polar liquid to a surface of the template substrate, or to a surface of the flexible storage medium, or to the surface of the template substrate and the surface of the flexible storage medium. The polar liquid is thereby brought into liquid contact with the nanofibres and the surface of the template substrate, either prior to or during contacting the template substrate and the flexible storage medium.

The transfer process may prior to the steps a) or a3) above include releasing the nanofibres from the template substrate by first exposing a surface of the template substrate to a controlled atmosphere comprising a polar vapour, or exposing a surface of the flexible storage medium, or exposing the surface of the template substrate and the surface of the flexible storage medium. The polar vapour is thereby brought into contact with the nanofibres and the surface of the template substrate, either prior to or during contacting the template substrate and the flexible storage medium.

The polar liquid or vapour provided to the surface of the substrate may wet the entire surface, may wet the regions abutting the nanofibres, or may at least provide sufficient polar molecules in an interface region between the nanofibres and the template substrate or the flexible storage medium. The liquid may, but need not to, cover the individual nanofibres. The polar liquid may be such a polar liquid as water or methanol, or any liquid which has a finite dipole moment, such as a dipole moment larger than 1 Debye, larger than 1.5 Debye, larger than 1.75 Debye, larger than 2 Debye or even larger.

The transfer process may comprise supplying energy to the combined system of nanofibres and liquid or nanofibres and vapour, the energy may be provided in the form of ultra-violet light. The energy may also be supplied by acoustic waves such as ultrasound.

In an embodiment, the nanofibres may be provided to the template substrate, by transferring the nanofibres to the template substrate from a liquid solution. Storing nanofibres in a liquid solution may be an intermediate step for redistributing the nanofibres before transferring the nanofibres to the template substrate. The provision of nanofibres to a liquid solution is disclosed in WO 2006/048015, which is hereby included by reference.

The organic nanofibres may be optically active elements, as they may emit light, e.g. by running a current along the fibre or by a fluorescence process following light or electron exposure of the nanofibres. The organic nanofibres may be optically active in the visible or near visible wavelength range, such as in the wavelength range of 300-600 nm, or more specific in the range of 370-500 nm, corresponding substantially to blue light. The organic nanofibres may, however, be optically active in any visible or near visible wavelength range, as determined by the electronic structure of the molecular constituents of the nanofibres.

Having transferred the nanofibres to the storage medium, the nanofibres may bond to the storage medium with sufficient strength, so that during handling and storage of the flexible storage medium, the nanofibres are not released form the storage medium. In order to release the nanofibres from the storage medium it may be necessary to perform at least some of the steps of embodiments of the present invention.

The method of releasing and transferring the nanofibres from a template substrate to a storage medium and optionally to a target substrate as disclosed, ensures that at least one, and possibly more, or even all, physical properties of the individual or ensemble of nanofibres are substantially unaltered in the release and/or transferring process. For example, the optical and morphological properties of individual or an ensemble of nanofibres may be conserved during transfer. However, also electronic and mechanical properties may be conserved in the transfer process. The nanofibres which are provided on the template may be aligned. The alignment of the individual nanofibres may as an example be substantially maintained in the transfer and storage process. An advantage of embodiments of the present invention may be that it ensures controlled aligned transfer of nanofibres.

In accordance with a second aspect of the present invention a flexible storage medium loaded with nanofibres is provided by applying the method of the first aspect.

The invention may be used in connection with the fabrication of devices such as light emitting devices, light sensing devices, light guiding devices, etc., that utilises laid-down nanofibres. The devices may be provided by a fabrication process where nanofibres forming light emitting, sensing or guiding elements have been provided onto a flexible storage medium and transferred to another substrate by the method according to embodiments of the invention.

The method according to the present invention is advantageous for use in the production of optoelectric components or devices since the active elements may be provided on a first substrate enabling growth or production of the nanoscale element and afterwards transferred to a storage medium, before transferred to a production substrate. The method may thereby bridge the gap often seen between specialised research on idealised model systems to commercial products. Further, it may render large-scale production cheap since it facilitates wafer-size production in a simple and reliable manner.

These and other aspects, features and/or advantages of the invention will be apparent from and elucidated with reference to the embodiments described hereinafter.

### BRIEF DESCRIPTION OF THE FIGURES

Embodiments of the invention will be described, by way of example only, with reference to the drawings, in which

FIG. 1 schematically illustrates the growth of organic nanofibres on a template substrate;

FIG. 2 shows two microscope images of aligned nanofibres;

FIGS. 3A-3D schematically illustrate the transfer process of the nanofibres from the template substrate to the flexible storage medium;

FIGS. 4A-4C schematically illustrate the transfer process of the nanofibres from the flexible storage medium to the target substrate;

FIGS. 5 A and B schematically illustrate the process of loading a flexible storage medium with nanofibres.

FIG. 6 is a schematically illustration of a loaded flexible storage medium in the form of a rolled band.

### DESCRIPTION OF EMBODIMENTS

Embodiments of the present invention relate to the transferring of nanofibres from a template substrate to a flexible storage medium. In a step prior to the transfer process, a template substrate supporting nanofibres as well as the flexible storage medium are provided.

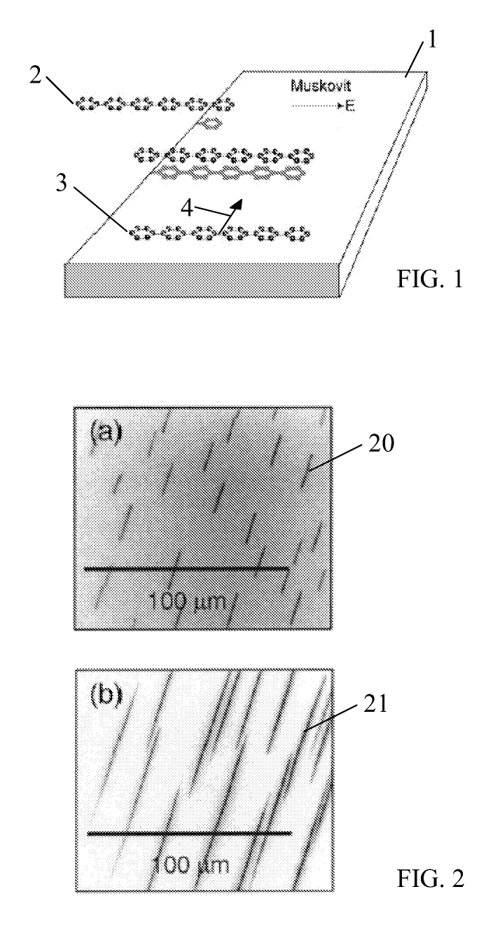

FIGS. 1 and 2 describe embodiments of a possible template substrate and nanofibres in the form of elongate aligned nanofibres of organic molecules grown on a mica substrate.

FIG. 1 schematically illustrates the growth of organic nanofibres 2, 3 on a template substrate 1, or more specifically, the growth of phenylene nanofibres on a muscovite mica substrate.

Mica may be prepared so that an electric field is present in the surface, e.g. by cleavage in air and immediate transfer into a vacuum apparatus where it may be outgassed, e.g. at 410 K for 0.5 h or possible longer, or by direct cleavage in vacuum.

The nanofibres presented in this section are made up of p-phenylene oligomers (p-nP) which are elongate molecules made of n benzene rings. It is however to be understood that any type of molecules within the scope of the present invention may be used. These molecules may grow in a self-organising way into organic nanofibres. The molecules grow in a direction perpendicular to the molecular axis, i.e. the molecules grow in a direction parallel to the surface plane, as indicated by the arrow marked with reference numeral 4. The fibres may be provided with a length of up to a few millimetres with a cross-section of a few hundreds nanometers. The size of the nanofibres can be controlled by implying proper conditions during the growth process.

The phenylene oligomers may be provided onto the mica surface at variable surface temperatures such as between 350 and 450 K, and with variable deposition rates, e.g. by means of a resistively heated oven with a nozzle at a deposition rate of ˜0.02-0.5 Å/S. The size of the resulting nanofibres depends very much on the surface temperature. The surface temperature may further be controlled by means of irradiating a focussed low power laser on the surface in the growth region.

FIGS. 2A and B show two microscope images of aligned nanofibres 20, 21 grown on a mica substrate. The nanofibres were grown at a surface temperature of 356 K in connection with laser irradiation from a 0.5 W laser. The width of the nanofibres is around 200 nm and the density is between 10⁵ cm⁻² and 10⁶ cm⁻². The typical lengths of the nanofibres are indicated by the scale bars provided in the Figures.

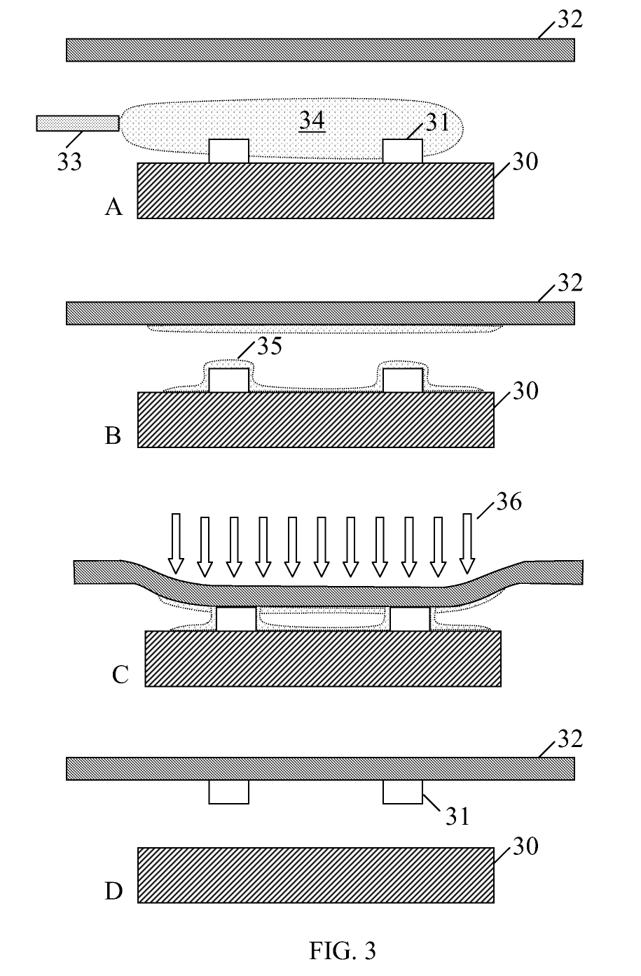

FIGS. 3A-3D schematically illustrate and in a cross-sectional view the transfer process of the nanofibres 31 from the template substrate 30 to the flexible storage medium 32. The illustration is purely provided for illustrative purposes and does not necessarily represent the physical truth at the interface.

The flexible storage medium may be in the form of a plastic band, such as a PET band.

In FIG. 3A the template substrate 30 supporting nanofibres 31 is exposed to water vapour 34 emitted from a nozzle 33 so that the surface of the template substrate is exposed to an atmosphere of a polar vapour. Also the surface of the flexible storage medium may be, but need not be, or may as an alternative be exposed to the vapour. The nozzle may generate a local ambient with a humidity of 80% for 0.5 to 5 seconds. The nozzle may be in the form of a nebulizer which is capable of creating a controlled flux of cold vapour, however alternative means may be used.

After the exposure a thin film 35 of the liquid has formed on the surface of the template substrate and possible also on the surface of the flexible storage medium 32, or at least water molecules have interacted with the nanofibres. As disclosed in WO 2006/048015, the interaction between the nanofibres and polar molecules result in a release of the nanofibres from the substrate, or at least in a weakening of the bonding between the nanofibres and the template substrate. This is illustrated in FIG. 3B.

In a next step, as illustrated in FIG. 3C the flexible storage medium or at least the area to be contacted, is pressed 36 in contact with the surface of the template substrate. The pressing may be done by means of a stamp pressing from the backside of the storage medium, and more specifically as illustrated in the Figure, the pressing may be done by means of a stamp utilizing compressed air 36 for forcing the flexible storage medium into contact with the template substrate and the nanofibres. In an embodiment 20 bar of compressed air may be applied, the pressure may be build up by an increase of 1 bar/sec.

By contacting the substrate and the storage medium together, the nanofibres form surface bonds to the storage medium and stick thereto. Upon separation, the nanofibres 31 or at least a large fraction of the nanofibres are transferred to the storage medium 32. The nanofibres are transferred in a way so that both the geometrical orientation of the nanofibres on the template substrate is maintained on the storage medium, also the physical properties of the nanofibres are maintained in the transfer process.

Compact storage of nanofibres for future use is thereby enabled.

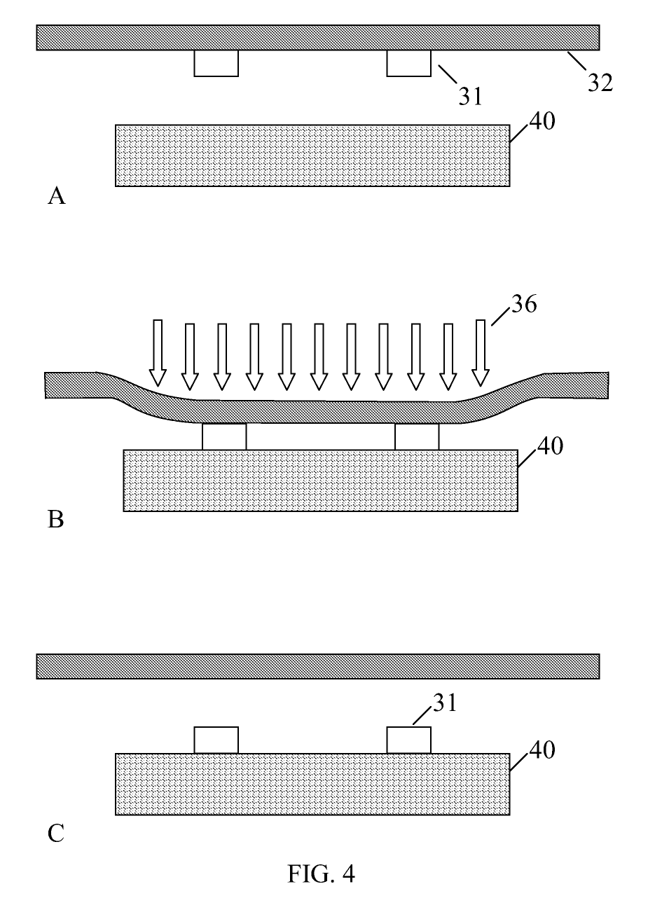

FIGS. 4A-4C schematically illustrate and in a cross-sectional view the transfer process of the nanofibres 31 from the flexible storage medium 32 to a target substrate 40. In FIG. 4A, the flexible storage medium is positioned so that the flexible storage medium is facing a target substrate 40, and as illustrated in FIG. 4B the flexible storage medium or at least the area to be contacted, is pressed 36 in contact with the surface of the template substrate, in a similar manner as in connection with FIG. 3C.

By contacting the storage medium and the target substrate together, the nanofibres are forming surface bonds to the target substrate and stick thereto. Upon separation, the nanofibres 31 or at least a large fraction of the nanofibres are transferred to the target substrate 40, as illustrated in FIG. 4C. Again, the nanofibres are transferred in a way so that both the geometrical orientation of the nanofibres on the template substrate is maintained on the storage medium, Also the physical properties of the nanofibres are maintained in the transfer process.

The target substrate may be any type of substrate, whereby nanofibres can be provided on a substrate on which growth of desired nanofibres may not be possible.

In addition to the process steps as described in connection with FIGS. 3 and 4, a process step of supplying energy, e.g. in the form of ultra-violet light, to the combined system of nanofibres and liquid or nanofibres and vapour may be applied.

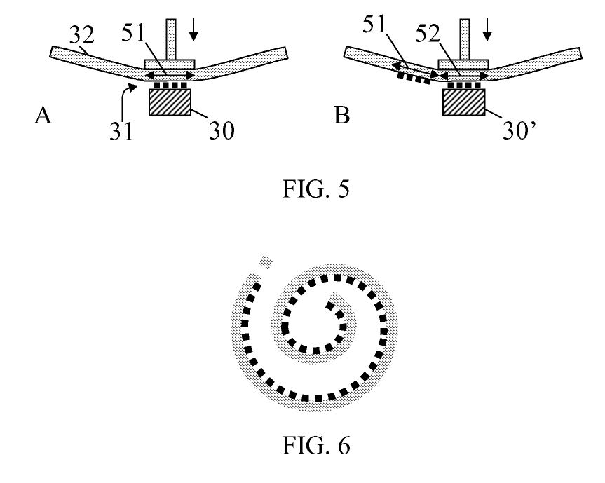

FIGS. 5A and 5B schematically illustrate the process of loading a flexible storage medium with a number of areas storing nanofibres.

In a first step, as illustrated in FIG. 5A, a template substrate 30 supporting nanofibres 31 and the flexible storage medium 32 are positioned with respect to each other so that a first storage area 51 of the flexible storage medium is facing a first support area of the template substrate. Typically, the first support area of the template substrate is the entire free surface of the template substrate, however the first support area may be a part of the template substrate.

As disclosed in connection with FIG. 3, the nanofibres are transferred to the flexible storage medium. A typical area of the template substrate is 25×25 mm or 25×75 mm. The size of the template substrate may be dictated by the size of a single domain of nanofibres on the specific template substrate. A single domain of 25×25 mm or 25×75 mm may be achieved for p-nP grown on Mica.

In a next step, as illustrated in FIG. 5B, nanofibres are provided onto the same or other template substrate 30′. The template substrate may after the prior transfer process be re-cleaved and a new layer of nanofibres may be grown on the substrate. The flexible storage medium is repositioned so that at least a second storage area 52 of the flexible storage medium is facing the support area of the template substrate.

Again, as disclosed in connection with FIG. 3, the nanofibres are transferred to the flexible storage medium.

This process may then be continued for a number of times, so that the flexible storage medium may be loaded with a number of areas supporting nanofibres.

In other embodiments, the template substrate may comprise two or more areas supporting nanostructures, each area to be transferred separately. In such embodiments, the template substrate may be repositioned before a second or next area of the storage medium is loaded with nanofibres.

FIG. 6 is a schematically illustration of a loaded flexible storage medium in the form of a rolled band. The loaded flexible storage medium may be stored for a period of time, for example in a controlled or protected atmosphere.

In order to transfer the nanofibres from a loaded storage medium and onto a target substrate, the reverse process of the process disclosed in connection with FIG. 5 may be applied.

The transfer of the nanofibres to a target substrate may be a step in a process of fabricating a device. The target substrate may e.g. be a semiconductor substrate, on which lithographic steps can be performed.

Although the present invention has been described in connection with preferred embodiments, it is not intended to be limited to the specific form set forth herein. Rather, the scope of the present invention is limited only by the accompanying claims.

In this section, certain specific details of the disclosed embodiment such as specific substrates, liquids, molecules, preparation conditions, as well as number and order of method steps, etc, are set forth for purposes of explanation rather than limitation, so as to provide a clear and thorough understanding of the present invention. However, it should be understood readily by those skilled in this art, that the present invention may be practised in other embodiments which do not conform exactly to the details set forth herein, without departing significantly from the spirit and scope of this disclosure. Further, in this context, and for the purposes of brevity and clarity, detailed descriptions of well-known apparatus, circuits and methodology have been omitted so as to avoid unnecessary detail and possible confusion.

Although the present invention has been described in connection with the specified embodiments, it should not be construed as being in any way limited to the presented examples. The scope of the present invention is to be interpreted in the light of the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

1-35. (canceled)

36. Method of transferring organic nanofibres from a template substrate to a flexible plastic storage medium so that the geometrical orientation of the nanofibres on the template substrate is maintained on the storage medium, the method comprising:
a) providing a template substrate with organic nanofibres grown on said template substrate in a direction parallel to a surface of the template substrate;
b) providing a flexible plastic storage medium in a position so that a first storage area of the storage medium is facing a first surface area of the template substrate;
c) releasing organic nanofibres from the template substrate by providing a polar liquid or vapour to a surface of the template substrate, or to a surface of the storage medium, or to both;
d) pressing the first storage area of the storage medium in contact with the first surface area of the template substrate and remove the first storage area of the storage medium from contact with the first surface area of the template substrate, thereby transferring the organic nanofibres from the template substrate to the storage medium and thereby providing a flexible plastic storage medium loaded with nanofibres having their geometrical orientation from when grown on the template substrate.

37. The method according to claim 36, further comprising:
b2) repositioning the storage medium and optionally the template substrate so that at least a second storage area of the storage medium is facing at least a second surface area of the template substrate.
d2) pressing the second storage area of the storage medium in contact with the at least second surface area of the template substrate and remove the at least second storage area of the storage medium from contact with the at least second surface area of the template substrate.

38. The method according to claim 36, further comprising:
a3) growing organic nanofibres onto the same or other template substrate;
b3) repositioning the storage medium so that at least a second storage area of the storage medium is facing a first surface area of the template substrate.
d3) pressing the second storage area of the storage medium in contact with the first surface area of the template substrate and remove the at least second storage area of the storage medium from contact with the first surface area of the template substrate.

39. The method according to claim 36, further comprising storing in a controlled atmosphere the flexible plastic storage medium loaded with nanofibres.

40. The method according to claim 36, further comprising:
e) providing a target substrate;
f) positioning the storage medium loaded with nanofibres so that a first storage area of the storage medium loaded with nanofibres is facing a first surface area of the target substrate;
g) pressing the first storage area of the storage medium loaded with nanofibres in contact with the first surface area of the target substrate and remove the first storage area of the storage medium from contact with the first surface area of the target substrate, thereby transferring the nanofibres from the storage medium loaded with nanofibres to the target substrate.

41. The method according to claim 40, further comprising:
f2) repositioning the storage medium loaded with nanofibres and optionally the target substrate so that at least a second storage area of the storage medium loaded with nanofibres is facing at least a second surface area of the target substrate.
g2) pressing the second storage area of the storage medium loaded with nanofibres in contact with the at least second surface area of the target substrate and remove the at least second storage area of the storage medium loaded with nanofibres from contact with the at least second surface area of the target substrate.

42. The method according to claim 36, wherein prior to step a), the organic nanofibres are released from the template substrate by first exposing a surface of the template substrate to a controlled atmosphere comprising a polar vapour or exposing a surface of the storage medium, or exposing the surface of the template substrate and the surface of the storage medium.

43. The method according to claim 38, wherein prior to step a3), the organic nanofibres are released from the template substrate by first exposing a surface of the template substrate to a controlled atmosphere comprising a polar vapour or exposing a surface of the storage medium, or exposing the surface of the template substrate and the surface of the storage medium.

44. The method according to claim 36, wherein the organic nanofibres are aligned.

45. Method according to claim 36, wherein the optical and morphological properties of individual or an ensemble of organic nanofibres are conserved during transfer from the template substrate to the storage medium.

46. Method according to claim 36, wherein the optical and morphological properties of individual or an ensemble of organic nanofibres are conserved during transfer from the storage medium loaded with nanofibres to the target substrate.

47. Method according to claim 36, wherein the organic molecules of the organic nanofibres are para-phenylene oligomers.

48. Method according to claim 36, wherein the pressing is done by means of a stamp, pressing from the backside of the storage medium.

49. Method according to claim 36, wherein the stamping is done by means of compressed air.

50. Method according to claim 36, wherein the storage medium is made of PET.

51. Flexible plastic storage medium loaded with organic nanofibres, the organic nanofibres having a geometrical orientation on the storage medium corresponding to a geometrical orientation in which they were originally grown on a template substrate.
